(19) United States
(12) Patent Application Publication
(10) Pub. No.: US 2018/0370463 A1
(43) Pub. Date: Dec. 27, 2018

(54) CIRCUIT ASSEMBLY AND ELECTRICAL JUNCTION BOX

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventors: Akira Haraguchi, Yokkaichi (JP); Arinobu Nakamura, Yokkaichi (JP)

(21) Appl. No.: 15/775,952

(22) PCT Filed: Dec. 7, 2016
(86) PCT No.: PCT/JP2016/086460

§ 371 Date: May 14, 2018

(30) Foreign Application Priority Data
Dec. 16, 2015 (JP) 2015-244888

(51) Int. Cl. B60R 16/023; H05K 1/11; H02G 3/03; H02G 3/16; H05K 1/02

(52) U.S. Cl. CPC B60R 16/0239; B60R 16/0238; H05K 1/115; H02G 3/03; H05K 1/0386; H05K 1/0203; H05K 2201/10272; H05K 2201/0959; H02G 3/16

(57) ABSTRACT

A circuit assembly includes a circuit board including a control circuit for controlling the flow of electric current in a power circuit is integral with the top of a plate-shaped busbar. The circuit assembly includes a circuit board in which both sides are provided with circuit patterns and having a via hole for electrically connecting the circuit patterns to each other, an adhesive sheet is interposed between the busbar and the circuit board and fixes the circuit board to the top of the busbar, a hole filling resin fills the via hole, and a resist layer is formed on at least a side of the circuit board that faces the busbar, covering the via hole filled with the hole filling resin. The adhesive sheet includes a substrate made of an insulating material, and adhesive layers are formed on both sides of the substrate and are sticky at room temperature.

### CROSS-REFERENCE TO RELATED APPLICATIONS

This application is the U.S. national stage of PCT/JP2016/086460 filed Dec. 7, 2016, which claims priority of Japanese Patent Application No. 2015-244888 filed on Dec. 16, 2015, which is incorporated herein by reference in its entirety.

### FIELD OF THE INVENTION

The present disclosure relates to a circuit assembly and an electrical junction box.

### BACKGROUND OF THE INVENTION

Conventionally, an electrical junction box (which is also called a power distributor) for distributing power from a power source (battery) to loads such as headlights and windshield wipers is mounted in an automobile. The electrical junction box includes a busbar that is connected to the power source and is part of a power circuit, and a circuit board including a control circuit for controlling the flow of electric current in the power circuit. The control circuit includes a circuit pattern formed on the circuit board, and electronic components such as switching elements (e.g., relays and FETs (field effect transistors)) and control elements (e.g., microcomputers and control ICs (integrated circuits).

In recent years, in order to reduce the size of the electrical junction box, circuit assemblies in which a circuit board is arranged integrally with the top of a busbar have been developed. JP 2005-117719A discloses a circuit assembly manufactured by using an adhesive sheet to bond the busbar and the circuit board together.

### SUMMARY OF THE INVENTION

A circuit assembly of the present disclosure is a circuit assembly in which a circuit board including a control circuit for controlling a flow of electric current in a power circuit is arranged integrally with a top of a plate-shaped busbar that is part of the power circuit, the circuit assembly including: a circuit board in which both sides are provided with circuit patterns and that is provided with a via hole for electrically connecting the circuit patterns to each other; a adhesive sheet that is interposed between the busbar and the circuit board and fixes the circuit board to the top of the busbar; a hole filling resin with which the via hole is filled; and a resist layer that is formed on at least a side of the circuit board that faces the busbar, covering the via hole filled with the hole filling resin, wherein the adhesive sheet includes a substrate made of an insulating material, and adhesive layers that are formed on both sides of the substrate and are sticky at room temperature.

An electrical junction box of the present disclosure includes: the above-mentioned circuit assembly of the present disclosure; a heat sink attached to the busbar; and a case accommodating the circuit assembly and the heat sink.

A typical example of the adhesive sheet in a conventional circuit assembly is an adhesive sheet in which a thermosetting epoxy-based adhesive is applied to both sides of a substrate made of a polyimide film. In the conventional circuit assembly, the busbar and the circuit board are bonded together by stacking the busbar and the circuit board with the adhesive sheet being sandwiched therebetween, and performing thermocompression bonding using a hot pressing apparatus.

The conventional circuit assembly is problematic in that manufacturing time is long due to thermocompression bonding and manufacturing cost increases because an apparatus such as a hot press apparatus is required, for example. In addition, residual stress may be generated in the circuit board and the solder for installing the electronic components due to repeated heating and cooling during thermocompression bonding, and cause the deformation of the circuit board and cracks in the solder. Therefore, there is a concern about an adverse influence on reliability. Furthermore, the epoxy-based adhesive is easy to deteriorate and needs to be stored at a low temperature, for example, and is thus difficult to store and handle.

Accordingly, the development of a circuit assembly that does not require thermocompression bonding and is superior in terms of productivity is in demand.

Therefore, an object of the present disclosure is to provide a circuit assembly that is superior in terms of productivity. In addition, another object of the present disclosure is to provide an electrical junction box including this circuit assembly.

The circuit assembly and the electrical junction box of the present disclosure are superior in terms of productivity.

### BRIEF DESCRIPTION OF THE DRAWINGS

FIG. 1 is a schematic perspective view of a circuit assembly according to Embodiment 1.

FIG. 2 is a schematic exploded perspective view of the circuit assembly according to Embodiment 1.

FIG. 3 is a schematic longitudinal cross-sectional view showing a relevant portion of the circuit assembly according to Embodiment 1.

FIG. 4 is a schematic longitudinal cross-sectional view showing a relevant portion of a circuit board provided with a via hole.

FIG. 5 is a schematic longitudinal cross-sectional view showing the relevant portion of the circuit board in which the via hole is filled with a hole filling resin.

FIG. 6 is a schematic longitudinal cross-sectional view showing the relevant portion of the circuit board on which a resist layer is formed.

FIG. 7 is a schematic perspective view of an electrical junction box according to Embodiment 1.

FIG. 8 is a schematic exploded perspective view of the electrical junction box according to Embodiment 1.

### DETAILED DESCRIPTION OF THE PREFERRED EMBODIMENTS

### Description of Embodiments of the Present Disclosure

The inventors of the present disclosure propose that in order to eliminate the need for thermocompression bonding, a gluing agent that is sticky at room temperature is used as an alternative material to a thermosetting adhesive (e.g., epoxy-based adhesive). First, embodiments of the present disclosure will be listed and described.

(1) A circuit assembly according to an aspect of the present disclosure is a circuit assembly in which a circuit board including a control circuit for controlling a flow of electric current in a power circuit is arranged integrally with a top of a plate-shaped busbar that is part of the power circuit, the circuit assembly including: a circuit board in which both sides are provided with circuit patterns and that is provided with a via hole for electrically connecting the circuit patterns to each other; a adhesive sheet that is interposed between the busbar and the circuit board and fixes the circuit board to the top of the busbar; a hole filling resin with which the via hole is filled; and a resist layer that is formed on at least a side of the circuit board that faces the busbar, covering the via hole filled with the hole filling resin, wherein the adhesive sheet includes a substrate made of an insulating material, and adhesive layers that are formed on both sides of the substrate and are sticky at room temperature.

With the above-mentioned circuit assembly, the busbar and the circuit board can be bonded together at room temperature using a adhesive sheet including adhesive layers that are sticky at room temperature without thermocompression bonding, thus making it easy to fix the circuit board to the top of the busbar. Accordingly, the thermocompression bonding can be omitted, and thus the manufacturing time can be reduced. In addition, an apparatus such as a hot pressing apparatus is also not required, thus making it possible to reduce production cost. Therefore, the above-mentioned circuit assembly is superior in terms of productivity. Furthermore, since the thermocompression bonding is not performed, the deformation of the circuit board and cracks in the solder caused by repeated heating and cooling can be prevented.

With the above-mentioned circuit assembly, the via hole is filled with the hole filling resin, thus making it possible to improve the reliability of insulation between the busbar and the circuit board. It is necessary to ensure electric insulation between the busbar and the circuit board in the circuit assembly. When a resist layer is formed on a side of the circuit board provided with the via hole, the side facing the busbar, the resist layer is not formed on the portion in which the via hole is provided, and the dielectric breakdown voltage between the circuit board and the busbar thus decreases. Therefore, sufficient electric insulation cannot be ensured in some cases. In the case of the circuit board in which the via hole is filled with the hole filling resin, the resist layer can be formed to cover the via hole due to the hole filling resin. Accordingly, with the above-mentioned circuit assembly, the resist layer is formed to cover the via hole, thus making it possible to suppress the decrease in the dielectric breakdown voltage due to the via hole and ensure the electric insulation between the busbar and the circuit board.

(2) In an embodiment of the above-mentioned circuit assembly, the adhesive layers are made of an acrylic gluing agent.

It is sufficient if a gluing agent that has electric insulating properties and is sticky at room temperature is used as the gluing agent for the adhesive sheet, and examples thereof include an acrylic gluing agent, a silicone-based gluing agent, and a urethane-based gluing agent. The adhesive layers are required to have a heat resistance against a solder reflow temperature at which the electronic components are installed. Furthermore, it is desired that the gluing agent is less likely to deteriorate at room temperature, has excellent shelf life, and is inexpensive. The acrylic gluing agent is favorable because it meets these required characteristics and is very sticky.

(3) In an embodiment of the above-mentioned circuit assembly, the substrate is a nonwoven fabric made of cellulose.

It is sufficient if a substrate that has electric insulating properties and a heat resistance against a solder reflow temperature is used as the substrate for the adhesive sheet, and examples thereof include nonwoven fabrics and resin films. Examples of the nonwoven fabrics include nonwoven fabrics containing cellulose fibers, nonwoven fabrics containing resin fibers, and nonwoven fabrics containing glass fibers, and examples of the resin fibers include polyimide fibers and polyamideimide fibers. Examples of the resin films include a polyimide film and a polyamideimide film. A nonwoven fabric made of cellulose, which is a sheet made of cellulose fibers, is favorable because it has a heat resistance against a solder reflow temperature and is relatively inexpensive.

(4) An electrical junction box according to an aspect of the present disclosure includes: the circuit assembly according to any one of (1) to (3) above; a heat sink attached to the busbar; and a case accommodating the circuit assembly and the heat sink.

The above-mentioned electrical junction box includes the above-mentioned circuit assembly according to an aspect of the present disclosure and is thus superior in terms of productivity. Moreover, in the above-mentioned electrical junction box, the heat sink is attached to the busbar of the circuit assembly, and therefore, heat generated in the circuit assembly can be dissipated to the heat sink, and the high reliability is achieved.

### Details of Embodiments of the Present Disclosure

Hereinafter, specific examples of the circuit assembly and the electrical junction box according to embodiments of the present disclosure will be described with reference to the drawings. In the figures, components having the same name are denoted by the same reference numeral. It should be noted that the present disclosure is not limited to these embodiments and is defined by the scope of the appended claims, and all changes that fall within the same essential spirit as the scope of the claims are intended to be included therein.

### Embodiment 1

Circuit Assembly

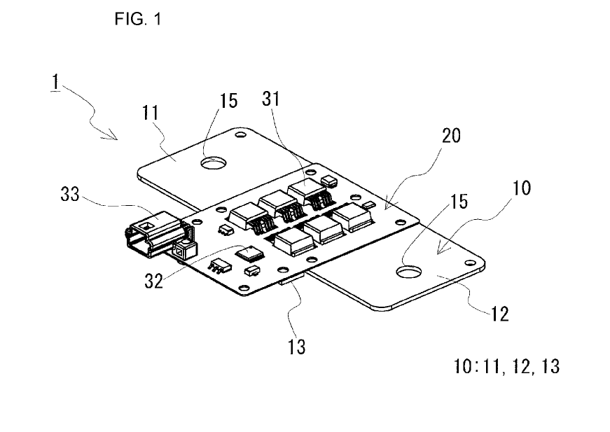

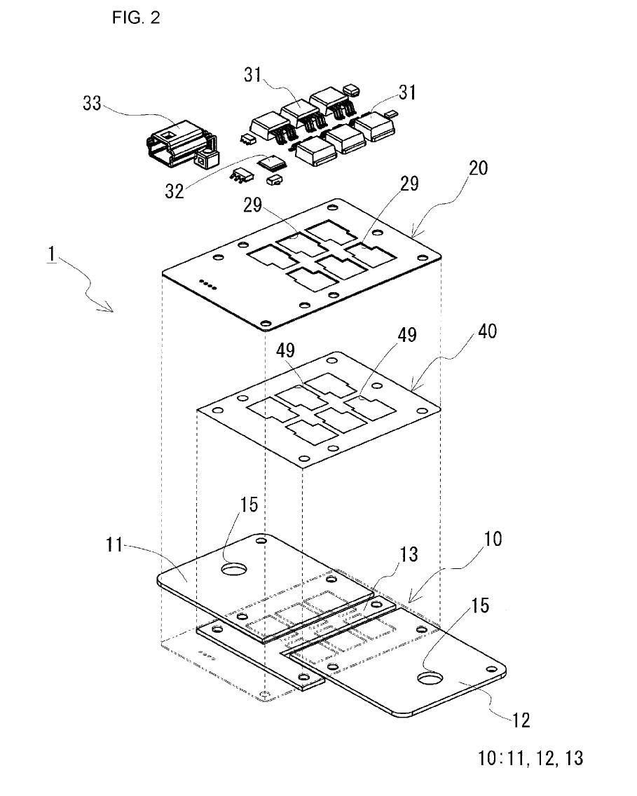

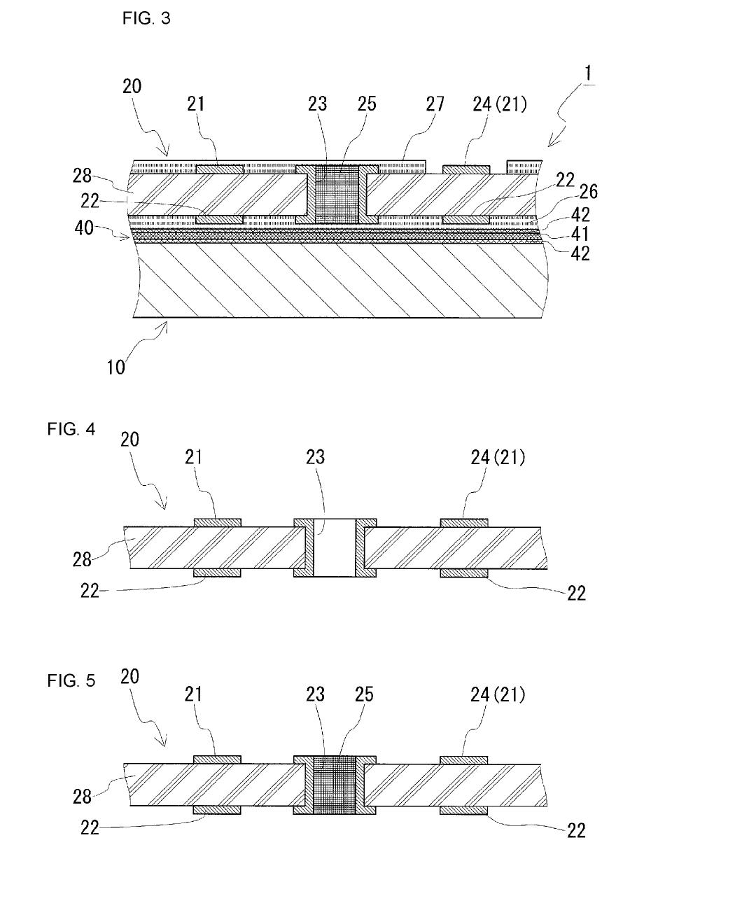

A circuit assembly of Embodiment 1 will be described with reference to FIGS. 1 to 6. As shown in FIGS. 1 to 3, a circuit assembly 1 of Embodiment 1 includes a plate-shaped busbar 10 and a circuit board 20, and the circuit board 20 is arranged integrally with the top of the busbar 10. One feature of the circuit assembly 1 of Embodiment 1 is that, as shown in FIGS. 2 and 3, a adhesive sheet 40 is provided between the busbar 10 and the circuit board 20, and the busbar 10 and the circuit board 20 are bonded together using the adhesive sheet 40. Another feature is that, as shown in FIG. 3, a hole filling resin 25 with which a via hole 23 formed in the circuit board 20 is filled, and a resist layer 26 formed on at least a side of the circuit board 20 that faces the busbar 10 to cover the via hole 23 filled with the hole filling resin 25 are provided. Hereinafter, the configuration of the circuit assembly 1 will be described in detail. In the following description, in the circuit assembly 1, the circuit board 20 side is referred to as “upper side”, and the busbar 10 side is referred to as “lower side”.

Busbar

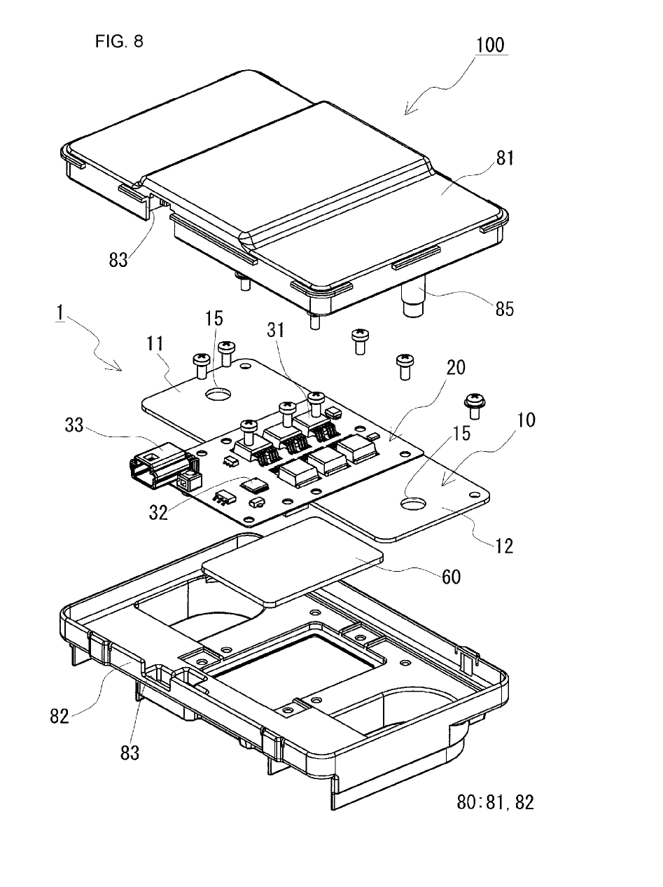

The busbar 10 is a plate-shaped component that is part of a power circuit. In this embodiment, as shown in FIG. 2, the busbar 10 includes a plurality of busbar pieces 11 to 13, and the busbar pieces 11 to 13 are arranged in a predetermined layout on the same plane. The busbar 10 (busbar pieces 11 to 13) is made of a conductive metal plate. Specifically, the busbar 10 is formed by cutting a plate material made of copper into a predetermined shape. The size of the busbar 10 (busbar pieces 11 to 13) is set to be suitable for an electric current flow amount and heat dissipation, and the thickness thereof is set to about 0.5 to 1.0 mm, for example. A wire harness 90 (see FIG. 7) is electrically connected to the busbar 10 as described later. In this embodiment, terminal insertion holes 15 into which power source terminals 85 (see FIGS. 7 and 8), which will be described later, can be inserted are formed in the busbar pieces 11 and 12, and the busbar pieces 11 and 12 can be electrically connected to the wire harnesses 90 via the power source terminals 85.

Circuit Board

As shown in FIGS. 1 to 3, the circuit board 20 is arranged on the busbar 10, and includes a control circuit for controlling the flow of electric current in the power circuit. As shown in FIG. 3, the circuit board 20 is a double-sided board (multilayer board) in which both sides are provided with circuit patterns 21 and 22, and that is provided with a via hole 23 for electrically connecting the circuit patterns 21 and 22 to each other. Specifically, the circuit board 20 is a printed circuit board obtained by printing the circuit patterns 21 and 22 on an insulated board 28, and the circuit patterns 21 and 22 are made of a copper foil. The circuit patterns 21 and 22 are respectively covered with resist layers 26 and 27, which will be described later. An exterior electronic control unit (not shown) can be connected to the circuit board 20.

As shown in FIG. 1, part of the terminals of FETs 31 and electronic components such as a microcomputer 32 and a control connector 33 are installed on the circuit board 20 through soldering. The microcomputer 32 is a control element for controlling the FETs 31 and the like. The control connector 33 is a connector to which an electronic control unit can be connected, and the electronic components operate based on the control signals from the electronic control unit. As shown in FIG. 3, lands 24 to which the components (not shown in FIG. 3) are joined through soldering are provided on the circuit pattern 21 on the upper side of the circuit board 20. The control circuit is constituted by the circuit patterns 21 and 22 formed on the circuit board 20, and the electronic components installed on the circuit board 20.

In this embodiment, another part of the terminals of FETs 31 is directly joined to the top of the busbar 10 through soldering. Therefore, as shown in FIG. 2, component openings 29 corresponding to the FETs 31 are formed at portions of the circuit board 20 at which the FETs 31 are to be arranged.

Hole Filling Resin

As shown in FIG. 3, the via hole 23 of the circuit board 20 is filled with the hole filling resin 25. As described later, the via hole 23 is filled with the hole filling resin 25 during the production of the circuit board 20 (see FIG. 5). An insulating resin is used as the hole filling resin 25, and an epoxy resin is used in this embodiment. The via hole 23 is filled with the hole filling resin 25 such that the upper and lower openings of the via hole 23 are each flush with the hole filling resin 25.

Resist Layer

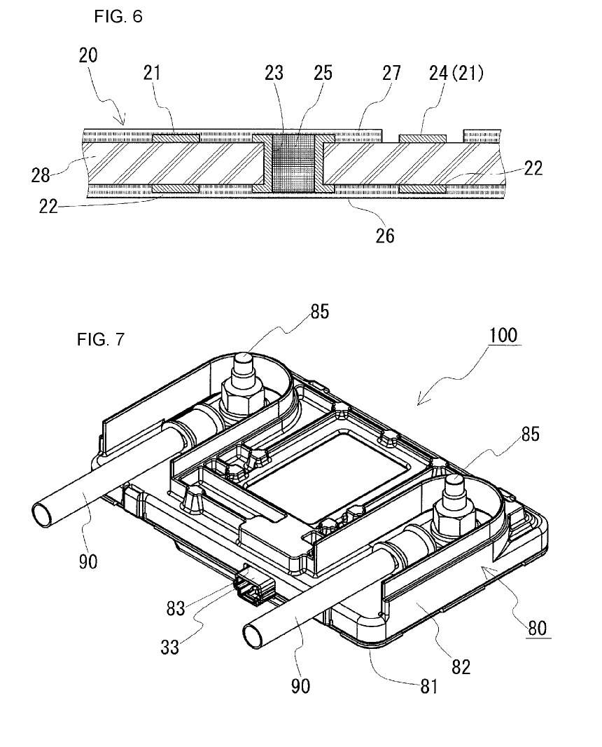

As shown in FIG. 3, the resist layer 26 is formed on the lower side (side facing the busbar 10) of the circuit board 20 to cover the via hole 23 filled with the hole filling resin 25. In this embodiment, the resist layer 27 is also formed on the upper side of the circuit board 20, and the portions at which the lands 24 are provided are not covered with the resist layer 27. The resist layers 26 and 27 are formed to protect the circuit patterns 21 and 22, maintain the electric insulation, and prevent solder from attaching to unnecessary portions during the installation of the electronic components. As described later, the resist layers 26 and 27 are formed during the production of the circuit board 20 by applying resist ink after the via hole 23 is filled with the hole filling resin 25 (see FIG. 6). The resist layers 26 and 27 are made of an insulating resin, and an epoxy resin is used as the insulating resin in this embodiment.

The thickness of the resist layer 26 is preferably 5 μm or more and more preferably 25 μm or more from the viewpoint of ensuring the electric insulation between the busbar 10 and the circuit board 20 (circuit pattern 22). The upper limit of the thickness of the resist layer 26 is 65 μm, for example, from the viewpoint of the adhesion with the circuit board 20 and the workability. The insulation resistance of the resist layer 26 is 500 MΩ or more, for example.

Adhesive Sheet

As shown in FIGS. 2 and 3, the adhesive sheet 40 is interposed between the busbar 10 and the circuit board 20 (resist layer 26) and fixes the circuit board 20 to the top of the busbar 10. As shown in FIG. 3, the adhesive sheet 40 includes a substrate 41 made of an insulating material, and adhesive layers 42 that are formed on both sides of the substrate 41 and are sticky at room temperature.

Substrate

The substrate 41 of the adhesive sheet 40 is made of a material that has a heat resistance against a solder reflow temperature (e.g., 260° C.) and electric insulating properties, and examples thereof include nonwoven fabrics containing cellulose fibers, nonwoven fabrics containing resin fibers, nonwoven fabrics containing glass fibers, a resin film made of polyimide, and a resin film made of polyamideimide. Examples of the resin fibers include polyimide fibers and polyamideimide fibers. Of these, a nonwoven fabric made of cellulose, which is a sheet made of cellulose fibers, is practical because it has a heat resistance against a solder reflow temperature and is relatively inexpensive. In this embodiment, a nonwoven fabric made of cellulose is used as the substrate 41. It is sufficient if the thickness of the substrate 41 is selected as appropriate such that the electric insulation between the busbar 10 and the circuit board 20 can be ensured, and the thickness of the adhesive sheet 40 including the adhesive layers 42 is set to 50 μm or more, for example.

The adhesive layers 42 of the adhesive sheet 40 are made of a gluing agent that has a heat resistance against a solder reflow temperature and electric insulating properties, and that is sticky at room temperature. Examples of the gluing agent include an acrylic gluing agent, a silicone-based gluing agent, and a urethane-based gluing agent. Of these, the acrylic gluing agent containing an acrylic polymer is practical because it is very sticky, has excellent shelf life due to the capability of being stored at room temperature, and is inexpensive. In this embodiment, the adhesive layers 42 are made of an acrylic gluing agent. The adhesive layers 42 are formed by applying a gluing agent to both sides of the substrate 41.

In this embodiment, as shown in FIG. 2, component openings 49 corresponding to the FETs 31 are formed in the adhesive sheet 40 at the same positions as those of the component openings 29 in the circuit board 20.

Method for Manufacturing Circuit Assembly

An example of a procedure for manufacturing the circuit assembly 1 of Embodiment 1 shown in FIG. 1 will be described with reference to FIGS. 2 to 6.

(1) The busbar 10, the circuit board 20, and the adhesive sheet 40 are prepared (see FIG. 2). The busbar 10 is produced by cutting a plate material made of oxygen-free copper into a predetermined shape. Specifically, the busbar 10 in which the busbar pieces 11 to 13 that each have a predetermined shape are arranged as shown in FIG. 2 is produced by punching a plate material made of oxygen-free copper.

The circuit board 20 is produced as follows. A board material is prepared that has been processed into a predetermined shape by forming the component openings 29 (see FIG. 2) and the like in a copper-clad laminate in which copper foils are laminated on both sides of the insulated board 28 (see FIG. 3). As shown in FIG. 4, the circuit patterns 21 and 22 are formed on the board material, and the via hole 23 is formed in the board material. Specifically, the via hole 23 for electrically connecting the copper foils on both sides is formed by forming a through hole at a predetermined position of the board material using a drill and plating the inner surface of the hole with copper, and the circuit patterns 21 and 22 are formed by etching the copper foils on both sides.

Next, as shown in FIG. 5, the hole filling resin 25 is formed by filling the via hole 23 with an epoxy resin and curing the epoxy resin. Then, as shown in FIG. 6, the resist layers 26 and 27 are formed by applying resist ink made of an epoxy resin to both sides of the circuit board 20 such that the via hole 23 is covered with the resist ink. When the resist layer 27 is formed, portions such as the lands 24 that are not covered with the resist layer 27 are masked, for example, such that the resist layer 27 is not formed on such portions. The circuit board 20 is thus produced.

The adhesive sheet 40 is produced by cutting, into a predetermined shape as shown in FIG. 2, a adhesive sheet in which both sides of the substrate 41 (see FIG. 3) made of a nonwoven fabric made of cellulose are provided with the adhesive layers 42 (see FIG. 3) made of an acrylic gluing agent.

(2) The busbar 10 and the circuit board 20 are bonded together using the adhesive sheet 40, and the circuit board 20 is thus fixed to the top of the busbar 10 (see FIG. 2). Specifically, the busbar 10 and the circuit board 20 are stacked with the adhesive sheet 40 being sandwiched therebetween, and the busbar 10 and the circuit board 20 are thus bonded together. As a result, the busbar 10 and the circuit board 20 are integrated.

(3) After the busbar 10 and the circuit board 20 are integrated, the electronic components are installed on the circuit board 20 (see FIG. 2). Specifically, solder paste is printed at the positions on the circuit board 20 at which the electronic components (e.g., FETs 31) are to be installed, and then the electronic components are placed. Thereafter, in a reflow furnace, the electronic components are joined to the top of the circuit board 20 through soldering. In this embodiment, the electronic components are also installed on the busbar 10, and therefore, solder paste is also printed on the busbar 10. The circuit assembly 1 shown in FIG. 1 is obtained through these steps.

Functions and Effects of Circuit Assembly

The circuit assembly 1 of Embodiment 1 exhibits the following effects.

(1) With the circuit assembly 1, as shown in FIG. 3, the busbar 10 and the circuit board 20 are bonded together using the adhesive sheet 40 in which both sides of the substrate 41 are provided with 1 the adhesive layers 42 that are sticky at room temperature. Therefore, the busbar 10 and the circuit board 20 can be bonded together at room temperature, and it is not necessary to perform thermocompression bonding unlike a conventional circuit assembly. Accordingly, with the circuit assembly 1, compared with a conventional circuit assembly, the thermocompression bonding can be omitted, and thus the manufacturing time can be reduced. In addition, an apparatus such as a hot pressing apparatus is also not required. Therefore, the productivity can be improved, and the manufacturing apparatuses can be simplified. The circuit assembly 1 is thus inexpensive and superior in terms of productivity. Furthermore, the deformation of the circuit board 20 and cracks in the solder resulting from residual stress caused by thermocompression bonding can be prevented, thus improving the reliability.

(2) With the circuit assembly 1, as shown in FIG. 3, the via hole 23 provided in the circuit board 20 is filled with the hole filling resin 25, and the resist layer 26 is formed on the side of the circuit board 20 that faces the busbar 10. Therefore, the resist layer 26 can be formed to cover the via hole 23 due to the via hole 23 being filled with the hole filling resin 25. In contrast, when the via hole 23 is not filled with the hole filling resin 25, the resist layer 26 is not formed on the portions at which the via hole 23 is provided in some cases. Accordingly, with the circuit assembly 1, the resist layer 26 is formed to cover the via hole 23 filled with the hole filling resin 25, and therefore, the dielectric breakdown voltage between the busbar 10 and the circuit board 20 increases compared with the case where the via hole 23 is not filled with the hole filling resin 25. As a result, the electric reliability between the busbar 10 and the circuit board 20 is high, and the electric insulation can be ensured.

(3) The adhesive layers 42 of the adhesive sheet 40 are made of an acrylic gluing agent, thus making it possible to firmly fix the circuit board 20 to the top of the busbar 10. The acrylic gluing agent is very sticky, has excellent shelf life due to the capability of being stored at room temperature, and is inexpensive, thus making it possible to improve the productivity and reduce the manufacturing cost.

(4) A nonwoven fabric made of cellulose is used as the substrate 41 of the adhesive sheet 40, thus making it possible to reduce the cost of the adhesive sheet 40 and reduce the manufacturing cost. For example, a polyimide film used as the substrate of the adhesive sheet in a conventional circuit assembly is expensive, whereas a nonwoven fabric made of cellulose is inexpensive. Therefore, use of the adhesive sheet in which the substrate is constituted by the nonwoven fabric made of cellulose makes it possible to reduce the cost of materials compared with the case where a conventional adhesive sheet is used.

Electrical Junction Box

Next, an electrical junction box 100 of Embodiment 1 will be described with reference to FIGS. 7 and 8. As shown in FIG. 8, the electrical junction box 100 of Embodiment 1 includes the circuit assembly 1, a heat sink 60, and a case 80. FIG. 7 is a diagram of the electrical junction box 100 as viewed from the lower side, and is inverted in the vertical direction compared with FIG. 8. Hereinafter, the configuration of the electrical junction box 100 will be described in detail. It should be noted that the circuit assembly 1 shown in FIG. 8 is the same as the above-described circuit assembly 1 of Embodiment 1 shown in FIG. 1, and identical constituents are denoted by identical reference numerals and the description thereof is omitted.

The heat sink 60 is attached to the busbar 10 of the circuit assembly 1. The heat sink 60 is made of a highly heat-conductive metal material such as aluminum or copper. In this embodiment, the heat sink 60 is an aluminum plate. There is no particular limitation on the shape of the heat sink 60, and the heat sink 60 may have a plate shape or a block shape. The heat sink 60 mainly serves to prevent the temperatures of the electronic components (e.g., FETs 31) installed in the circuit assembly 1 and the temperature of the solder for installing the electronic components from exceeding the acceptable temperatures. The size of the heat sink 60 is set to be suitable for heat dissipation, for example.

The heat sink 60 is attached to the circuit assembly 1 (busbar 10) through bonding using a adhesive sheet having a configuration similar to that of the adhesive sheet 40 (see FIG. 3) used in the circuit assembly 1, for example. In addition, the heat sink 60 may also be attached to the circuit assembly 1 (busbar 10) through bonding using an adhesive sheet in which an adhesive is applied to both sides of a substrate. When the adhesive sheet is used, it is not necessary to perform thermocompression bonding, and therefore, the production cost can be reduced, which is advantageous in terms of the productivity.

The case 80 accommodates the circuit assembly 1 and the heat sink 60. In this embodiment, as shown in FIG. 8, the case 80 includes an upper case 81 and a lower case 82. Rod-shaped power source terminals 85 extending toward the lower case 82 are provided inside the upper case 81. The power source terminals 85 are inserted into the terminal insertion holes 15 formed in the busbar 10 (busbar pieces 11 and 12) of the circuit assembly 1, and are electrically connected to the busbar 10. As shown in FIG. 7, the power source terminals 85 protrude from the case 80 to the outside via through holes formed in the lower case 82, and the wire harnesses 90 are attached to the ends of the power source terminals 85 protruding from the case 80 to the outside. As a result, the busbar 10 is electrically connected to the wire harnesses 90 via the power source terminals 85. A connector opening 83 is formed in the case 80 such that the control connector 33 of the circuit assembly 1 is exposed from the case 80 to the outside.

Method for Manufacturing Electrical Junction Box

An example of a procedure for manufacturing the electrical junction box 100 of Embodiment 1 shown in FIG. 7 will be described with reference to FIG. 8.

After the heat sink 60 is bonded to the lower side of the busbar 10 of the circuit assembly 1, the circuit assembly 1 is attached and fixed to the inside of the lower case 82 using screws. Then, the case 80 is assembled by fitting the upper case 81 to the lower case 82. The electrical junction box 100 shown in FIG. 7 is thus obtained.

### Test Examples

Circuit assemblies of samples 1 to 3 as described below were produced and evaluated.

Sample 1 was the above-described circuit assembly of Embodiment 1. In the circuit assembly of sample 1, a adhesive sheet in which an acrylic gluing agent was applied to both sides of a substrate constituted by a nonwoven fabric made of cellulose was used, and the busbar and the circuit board were bonded together using the adhesive sheet. The via hole of the circuit board was filled with the hole filling resin made of an epoxy resin, and a resist layer made of an epoxy resin was formed on the lower side of the circuit board to cover the via hole. The adhesive sheet had a thickness of 50 μm, and the resist layer had a thickness of 25 μm.

Sample 2 was produced in the same manner as in sample 1, except that the via hole of the circuit board was not filled with the hole filling resin made of an epoxy resin.

In sample 3, an adhesive sheet in which an epoxy-based adhesive was applied to both sides of a substrate made of a polyimide film was used instead of the adhesive sheet of sample 1. The adhesive sheet was sandwiched between the busbar and the circuit board, and then the busbar and the circuit board were bonded together through thermocompression bonding. In the circuit assembly of sample 3, similarly to sample 2, the via hole of the circuit board was not filled with the hole filling resin made of an epoxy resin. The substrate of the adhesive sheet had a thickness of 25 μm.

The circuit assemblies of samples 1 to 3 were subjected to a withstand voltage test in which a D.C. voltage of 0.8 to 2.0 kV is applied between the circuit board and the busbar, and the electric insulation was evaluated. When dielectric breakdown occurred, the electric insulation was evaluated as “A”, and when dielectric breakdown did not occur, the electric insulation was evaluated as “B”. Table 1 shows the results.

TABLE 1

| Sample | Test voltage (kV) | | | | | | |
|---|---|---|---|---|---|---|---|
| No. | 0.8 | 1.0 | 1.2 | 1.4 | 1.6 | 1.8 | 2.0 |
| 1 | A | A | A | A | A | A | A |
| 2 | A | A | A | A | A | B | — |
| 3 | A | A | A | A | A | A | A |

It is found from the results shown in Table 1 that dielectric breakdown did not occur at a voltage of up to 2.0 kV in the circuit assembly of sample 1, and high electric insulation for DC 2 kV or more was achieved. In contrast, dielectric breakdown occurred at a voltage of 1.8 kV in the circuit assembly of sample 2. The dielectric breakdown voltage of this circuit assembly was lower than that of the circuit assembly of sample 1, and the electric insulation decreased. It is thought that sufficient electric insulation was ensured due to the resist layer and the adhesive sheet in sample 1 because the via hole was filled with the hole filling resin and the resist layer was formed to cover the via hole filled with the hole filling resin.

Dielectric breakdown did not occur at a voltage of up to 2.0 kV in the circuit assembly of sample 3, and similarly to sample 1, high electric insulation was achieved. However, in sample 3, it was necessary to perform thermocompression bonding. Therefore, compared with sample 1, operations were more complicated, and the productivity was poorer. In addition, the polyimide film used as the substrate of the adhesive sheet in sample 3 was expensive, and the adhesive sheet was thus expensive. In contrast, in sample 1, a nonwoven fabric made of cellulose was used as the substrate of the adhesive sheet, and therefore, the adhesive sheet was more inexpensive than the adhesive sheet, thus making it possible to reduce the cost of materials.

Applications of Circuit Assembly and Electrical Junction Box

The circuit assembly and the electrical junction box according to the embodiment of the present disclosure can be favorably used in an electrical junction box for an automobile.

### LIST OF REFERENCE NUMERALS

1 Circuit assembly
100 Electrical junction box
10 Busbar
11 to 13 Busbar piece
15 Terminal insertion hole
20 Circuit board
21, 22 Circuit pattern
23 Via hole
24 Land
25 Hole filling resin
26, 27 Resist layer
28 Insulated board
29 Component opening
31 FET
32 Microcomputer
33 Control connector
40 Adhesive sheet
41 Substrate
42 Adhesive layer
49 Component opening
60 Heat sink
80 Case
81 Upper case
82 Lower case
83 Connector opening
85 Power source terminal
90 Wire harness

1. A circuit assembly in which a circuit board including a control circuit for controlling a flow of electric current in a power circuit is arranged integrally with a top of a plate-shaped busbar that is part of the power circuit, the circuit assembly comprising:
a circuit board in which both sides are provided with circuit patterns and that is provided with a via hole for electrically connecting the circuit patterns to each other;
an adhesive sheet that is interposed between the busbar and the circuit board and fixes the circuit board to the top of the busbar;
a hole filling resin with which the via hole is filled; and
a resist layer that is formed on at least a side of the circuit board that faces the busbar, covering the via hole filled with the hole filling resin,
wherein the adhesive sheet includes a substrate made of an insulating material, and adhesive layers that are formed on both sides of the substrate and are sticky at room temperature.

2. The circuit assembly according to claim 1, wherein the adhesive layers are made of an acrylic adhesive.

3. The circuit assembly according to claim 1, wherein the substrate is a nonwoven fabric made of cellulose.

4. An electrical junction box comprising:
the circuit assembly according to claim 1;
a heat sink attached to the busbar; and
a case accommodating the circuit assembly and the heat sink.
